(19) United States
(12) Patent Application Publication
(10) Pub. No.: US 2019/0058082 A1
(43) Pub. Date: Feb. 21, 2019

(54) UNIFORM SEMICONDUCTOR NANOWIRE AND NANOSHEET LIGHT EMITTING DIODES

(71) Applicant: GLOBALFOUNDRIES INC., Grand Cayman (KY)

(72) Inventors: Deepak K. NAYAK, Union City, CA (US); Srinivasa R. BANNA, San Jose, CA (US); Ajey P. JACOB, Watervliet, NY (US)

(21) Appl. No.: 15/678,385

(22) Filed: Aug. 16, 2017

(51) Int. Cl. H01L 33/00; H01L 33/06; H01L 33/08; H01L 33/12; H01L 33/24; H01L 33/32

(52) U.S. Cl. CPC H01L 33/007; H01L 33/06; H01L 33/32; H01L 33/12; H01L 33/24; H01L 33/08

(57) ABSTRACT

The present disclosure relates to semiconductor structures and, more particularly, to uniform semiconductor nanowire and nanosheet light emitting diodes and methods of manufacture. The structure includes a buffer layer; at least one dielectric layer on the buffer layer, the at least one dielectric layer having a plurality of openings exposing the buffer layer; and a plurality of uniformly sized and shaped nanowires or nanosheets formed in the openings and extending above the at least one dielectric layer.

### FIELD OF THE INVENTION

The present disclosure relates to semiconductor structures and, more particularly, to uniform semiconductor nanowire and nanosheet light emitting diodes and methods of manufacture.

### BACKGROUND

Light emitting diodes (LEDs) require optically transparent and highly conducting electrodes. In LEDs, a material is in contact with a charge collector in addition to a medium, such as an electrolyte that is inductive of electrochemical activity. When a suitable voltage is applied to leads of the LED device, electrons are able to recombine with electron holes within the LED device, releasing energy in the form of photons.

Two-dimensional (2D) LEDs are planar devices that emit light from a thin layer of material at or near their flat surface. On the other hand, in three-dimensional (3D) LEDs, light is capable of being emitted from all sides of a device. Manufacturing of 3D LEDs pose many issues including micro-loading of nanowires and nanosheets and spectral spread and yield loss due to non-uniform diameter nanowire or nanosheet LED leads.

### SUMMARY

In an aspect of the disclosure, a structure comprises: a buffer layer; at least one dielectric layer on the buffer layer, the at least one dielectric layer having a plurality of openings exposing the buffer layer; and a plurality of uniformly sized and shaped nanowires or nanosheets formed in the openings and extending above the at least one dielectric layer.

In an aspect of the disclosure, a method comprises: forming a first dielectric material on a buffer layer; forming a second dielectric on the first dielectric; etching a plurality of openings through the first dielectric and the second dielectric of the structure, stopping on the buffer layer; filling the plurality of openings with seed material; and removing the second dielectric of the structure to expose a plurality of nanowire or nanosheet seeds, which comport to a shape of the plurality of openings.

In an aspect of the disclosure, a method comprises: forming a first dielectric material directly on a buffer layer; forming a second dielectric material directly on the first dielectric material; etching a plurality of openings through the first dielectric material and the second dielectric material, exposing the buffer layer; growing nanowire or nanosheet seeds in the plurality of openings, from the exposed buffer layer; removing the second dielectric material to partially expose a plurality of uniformly shaped nanowires or nanosheets that comport with a shape of the plurality of openings; forming a plurality of quantum wells on sidewalls of the uniformly shaped nanowires or nanosheets; and forming at least one material on sidewalls of each of the plurality of quantum wells.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows an incoming structure and respective fabrication processes in accordance with aspects of the present disclosure.

FIG. 2 shows nanowires/nanosheets in an opening of dielectric material, amongst other features, and respective fabrication processes in accordance with aspects of the present disclosure.

FIG. 3 shows uniform nanowires/nanosheets, amongst other features, and respective fabrication processes in accordance with aspects of the present disclosure.

FIG. 4 shows nanowire/nanosheet light emitting diodes (LEDs), amongst other features, and respective fabrication processes in accordance with aspects of the present disclosure.

### DETAILED DESCRIPTION

The present disclosure relates to semiconductor structures and, more particularly, to uniform semiconductor nanowire and nanosheet light emitting diodes and methods of manufacture. More specifically, the present disclosure is directed to 3D LEDs with uniform nanowire or nanosheets. Advantageously, the present disclosure reduces the manufacturing cost in comparison to two-dimensional (2D) LEDs. In particular, the present disclose can reduce the manufacturing cost approximately three-fold over 2D LEDs. Further, the present disclosure provides for a same size nanowire or nanosheet and a same band gap, which results in tighter optical spectra distribution and manufacturing yield.

In the present disclosure, nanowires or nanosheets can be grown in uniform shapes, e.g., same circular or rectangular shapes. This is accomplished by growing nanowires or nanosheets in uniformly shaped openings in dielectric material. In embodiments, the openings are made by conventional patterning and etching processes, e.g., CMOS processes, which results in precise control of the nanowire or nanosheet seed diameter from pixel to pixel and from wafer to wafer. Thus, in the present disclosure, the manufacturing process obtains a uniform size for the nanowire or nanosheet LEDs.

The nanowire or nanosheet LED structures of the present disclosure can be manufactured in a number of ways using a number of different tools. In general, though, the methodologies and tools are used to form structures with dimensions in the micrometer and nanometer scale. The methodologies, i.e., technologies, employed to manufacture the semiconductor structure of the present disclosure have been adopted from integrated circuit (IC) technology. For example, the nanowire or nanosheet LED structures are built on wafers and are realized in films of material patterned by photolithographic processes on the top of a wafer. In particular, the fabrication of the nanowire or nanosheet LED structures uses three basic building blocks: (i) deposition of thin films of material on a substrate, (ii) applying a patterned mask on top of the films by photolithographic imaging, and (iii) etching the films selectively to the mask.

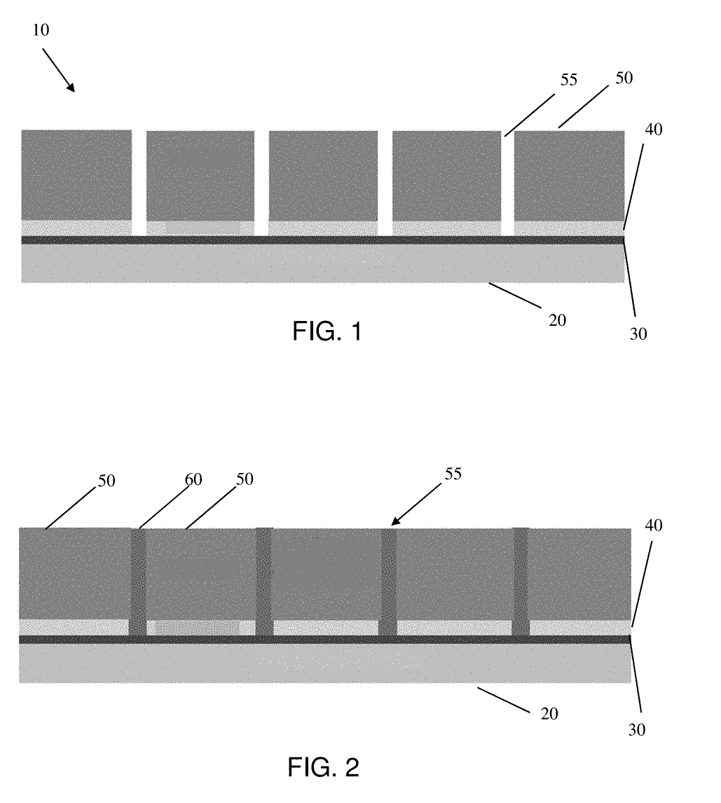

FIG. 1 shows an incoming structure and respective fabrication processes in accordance with aspects of the present disclosure. More specifically, the structure 10 of FIG. 1 includes a semiconductor or insulating material 20. In embodiments, the semiconductor or insulating material 20 can be composed of, e.g., Si, Sapphire, SiC or glass. A buffer layer 30 is formed on the material 20. The buffer layer 30 can be, e.g., GaN or metal nitride with a crystalline structure or other metal buffer layer, e.g., AN, WN, etc. In the embodiments, the buffer layer 30 will act as an etch stop layer during subsequent etching processes. In embodiments, the GaN layer can be deposited by a metal organic chemical vapor deposition (MOCVD) process with a thickness of approximately 500 nm to 5 microns. Alternatively, metal nitride can be deposited by a plasma-enhanced chemical vapor deposition (PECVD) process or other chemical vapor deposition (CVD) process to a thickness of approximately 50 nm to 150 nm.

Still referring to FIG. 1, a dielectric material 40 is formed on the buffer layer 30. The dielectric material 40 can be, e.g., SiN or oxide. In embodiments, the buffer layer 30 can be a passivated layer to either inhibit or enhance subsequent growth of GaN material. A dielectric material 50 is formed on the dielectric 40. The dielectric material 50 can be SiN or oxide. It should be understood, though, that the dielectric material 40 and the dielectric material 50 should preferably be of different materials to effectuate etching selectivity in subsequent processing steps.

In FIG. 1, openings 55 are formed through the dielectric material 40 and the dielectric material 50, exposing the underlying buffer layer 30. In embodiments, the openings 55 can be formed using conventional lithography and reactive ion etching (RIE) processes. For example, a resist formed over the dielectric material 50 is exposed to energy (light) to form a pattern (opening). An etching process with a selective chemistry, e.g., reactive ion etching (RIE), will be used to form one or more openings in the dielectric material 40 and dielectric material 50 through the openings of the resist. The etching process will stop on the etch stop layer 30. The resist can then be removed by a conventional oxygen ashing process or other known stripants.

In embodiments, the openings 55 are uniform, e.g., with the same size. In embodiments, the openings 55 can be changed to different dimensions to control and tune a color of the LEDs. For example, the dimensions of the openings 55 can be in a range of about 50 nm to 1 micron, with 70 nm being one preferred embodiment. In further embodiments, the openings 55 can be about 150 nm to 500 nm, and preferably between 150 nm to about 200 nm etc., to emit different colors in the LEDs. In embodiments, the openings 55 can be circular, rectangular or other shapes, all of which are of a same uniform shape to contain the growth of LED material, e.g., seed material for the nanowire, etc.

FIG. 2 shows nanowires/nanosheets in dielectric material, amongst other features, and respective fabrication processes in accordance with aspects of the present disclosure. More specifically, in embodiments, seed material, e.g., GaN material is formed within the openings 55 to form the nanowires/nanosheets 60. In embodiments, the seed material can be epitaxially grown in the openings 55 starting from the exposed buffer layer 30 to form a plurality of nanowires/nanosheets 60. As should be understood by those of skill in the art, the seed material will conform to the shapes of the openings 55 hence forming nanowires/nanosheets 60 each having a same size and shape based on the uniform dimensions (e.g., size and shape) of the openings 55.

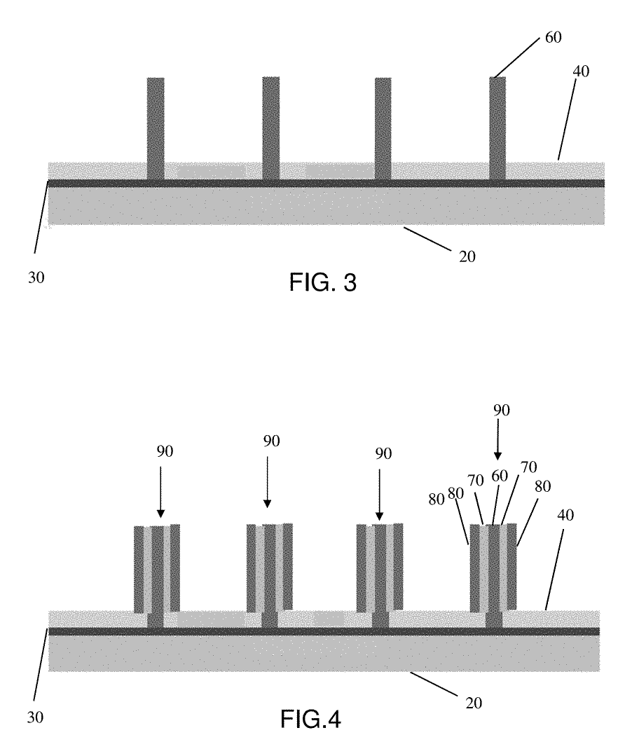

In FIG. 3, the dielectric material 50 is removed, partially exposing the uniform nanowires/nanosheets 60. More specifically, by using a selective etching chemistry, it is possible to remove the dielectric material 50 without removal of the dielectric material 40. In this way, the uniform nanowires/nanosheets 60 will remain, extending above the dielectric material 40.

FIG. 4 shows nanowire/nanosheet light emitting diodes (LEDs), amongst other features, and respective fabrication processes in accordance with aspects of the present disclosure. In particular, FIG. 4 shows a plurality of quantum wells 70 formed on each of the nanowires/nanosheets 60. The quantum wells 70 can be, e.g., GaN and InGaN, grown on the sides of the nanowires/nanosheets 60. It should be understood that the dielectric material 40 will prevent the growth of the quantum wells 70 on the dielectric material 40. A material 80 is formed over the quantum wells 70, More specifically, the material 80 is, e.g., a p-type GaN. The combination of the nanowires/nanosheets 60, quantum wells 70, and the material 80 will form uniform nanowire/nanosheet LEDs 90. Following the formation of the uniform nanowire/nanosheet LEDs 90, contacts and other back end of the line structures can be fabricated using conventional CMOS processes.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure, comprising:
a buffer layer;
at least one dielectric layer on the buffer layer, the at least one dielectric layer having a plurality of openings exposing the buffer layer;
a plurality of uniformly sized and shaped nanowires or nanosheets formed in the openings and extending above the at least one dielectric layer;
a plurality of quantum wells surrounding sidewalls of the uniformly sized and shaped nanowires or nanosheets; and
at least one material directly on sidewalls of the quantum wells,
wherein the at least one material comprises a p-type GaN.

2. The structure of claim 1, wherein each of the plurality of uniform sized and shaped nanowires or nanosheets has a same diameter.

3. (canceled)

4. The structure of claim 1, wherein each of the quantum wells comprise GaN and InGaN.

5.-6. (canceled)

7. The structure of claim 1, wherein the buffer layer is GaN.

8. The structure of claim 1, wherein the buffer layer is a metallic material.

9. The structure of claim 1, wherein the at least one dielectric layer comprises SiN.

10. The structure of claim 1, wherein the at least one dielectric layer comprises oxide.

11.-20. (canceled)

21. The structure of claim 1, wherein the at least one dielectric layer comprises a first dielectric layer on the buffer layer and a second dielectric layer on the first dielectric layer, the first dielectric layer comprising silicon nitride and the second dielectric layer comprising oxide.

22. The structure of claim 21, wherein each of the plurality of uniform sized and shaped nanowires or nanosheets have a same bandgap.

23. The structure of claim 22, wherein each of the openings are between about 150 nm to about 200 nm to allow for different colors to emit.

24. The structure of claim 23, wherein each of the openings are a same uniform circular shape to contain a growth of seed material from the plurality of uniformly sized and shaped nanowires or nanosheets.
